(19) United States
(12) Patent Application Publication
(10) Pub. No.: US 2026/0369196 A1
(43) Pub. Date: Nov. 19, 2026

(54) ELECTRONIC DEVICE AND INSPECTION METHOD OF DISPLAY PANEL

(71) Applicant: Samsung Display Co., Ltd., Yongin-si (KR)

(72) Inventor: SEONGJOO LEE, Yongin-si (KR)

(21) Appl. No.: 19/463,274

(22) Filed: Jan. 29, 2026

(30) Foreign Application Priority Data
May 13, 2025 (KR) 10-2025-0062088

(51) Int. Cl. G09G 3/00; G01R 31/28; G09G 3/20; G09G 3/3233

(52) U.S. Cl. CPC G09G 3/006; G01R 31/2825; G09G 3/2096; G09G 3/3233; G09G 2300/0819; G09G 2300/0852; G09G 2300/0861; G09G 2370/08

(57) ABSTRACT

An electronic device according to one or more embodiments of the present disclosure includes a flexible circuit board, and a display panel electrically connected with the flexible circuit board, and including pixels, data lines electrically connected with the pixels, a multiplexer configured to select at least one data line of the data lines, a test circuit configured to convert a line signal transferred through the at least one data line into a digital signal to output test data, and a test pad connected with the test circuit and configured to output the test data.

### CROSS-REFERENCE TO RELATED APPLICATION

The present application claims priority to, and the benefit of, Korean Patent Application No. 10-2025-0062088, filed on May 13, 2025, in the Korean Intellectual Property Office, the entire disclosure of which is incorporated herein by reference.

### BACKGROUND

The present disclosure relates to an electronic device and an inspection method of display panel with improved process efficiency.

An electronic device, such as a smartphone, a notebook computer, a navigation, and a smart television that provides an image to a user, include a display device for displaying an image. An augmented reality device, a virtual reality device, or a video projection device may include a micro display device. The micro display device may include a silicon wafer, and a light-emitting element located on the silicon wafer to display a high-brightness image while being driven at low power.

### SUMMARY

An aspect of the present disclosure provides an electronic device and a display panel inspection method with improved process efficiency.

An electronic device according to one or more embodiments of the present disclosure may include a flexible circuit board, and a display panel electrically connected with the flexible circuit board, and including pixels, data lines electrically connected with the pixels, a multiplexer configured to select at least one data line of the data lines, a test circuit configured to convert a line signal transferred through the at least one data line into a digital signal to output test data, and a test pad connected with the test circuit and configured to output the test data.

The multiplexer, the test circuit, and the test pad may be above the display panel.

The display panel may further include a timing controller configured to output an image data signal, and a driving circuit configured to provide a data signal to the data lines based on the image data signal.

The electronic device may further include a first chip on the flexible circuit board, and including a timing controller configured to output an image data signal, wherein the display panel further includes a driving circuit configured to provide a data signal to the data lines based on the image data signal.

The electronic device may further include a second chip on the display panel and including a timing controller configured to output an image data signal, and a driving circuit configured to provide a data signal to the data lines based on the image data signal.

The test circuit may include an operational amplifier configured to amplify a first voltage value of the line signal to a second voltage value having a voltage level that is higher than the first voltage value, and an analog-to-digital converter configured to convert the second voltage value into a digital signal to generate the test data output to the test pad.

The multiplexer may be provided in plural, and may include a first multiplexer and a second multiplexer, wherein the pixels include first pixels connected with the first multiplexer, and second pixels spaced apart from the first pixels in a first direction and connected with the second multiplexer.

The test circuit may be provided in plural to respectively correspond to the multiplexers, wherein the test pad is provided in plural to respectively correspond to the test circuits.

An electronic device according to one or more embodiments of the present disclosure includes a flexible circuit board, and a display panel electrically connected with the flexible circuit board, and including pixels, data lines electrically connected with the pixels, and driving circuits electrically connected with the data lines, and including a decoder configured to receive an image data signal from outside, an operational amplifier including a first input terminal, a second input terminal, and an output terminal, an analog-to-digital converter configured to convert an analog signal into a digital signal, a first switch connected between the decoder and the first input terminal, and a second switch connected between the analog-to-digital converter and the output terminal.

The electronic device may further include a first chip on the flexible circuit board, electrically connected with the display panel, and including a timing controller configured to output the image data signal.

The display panel may further include a timing controller configured to output the image data signal.

The driving circuits may further include a capacitor, a third switch connected between the second input terminal and the capacitor, a fourth switch connected between the output terminal and the capacitor, and a fifth switch connected between the output terminal and one of the data lines.

When the first switch and the fifth switch are connected, the driving circuits may be configured to operate as voltage followers.

The driving circuits may be configured to output a data voltage to the one of the data lines based on the image data signal, wherein the pixels are configured to receive the data voltage.

When the second switch, the third switch, and the fourth switch are connected, the driving circuits may be configured to operate as operational amplifiers.

The display panel may further include a test pad connected with the analog-to-digital converter.

In an inspection method of display panel including a silicon wafer, a pixel circuit on the silicon wafer, a data line connected with the pixel circuit, a test circuit connected with the data line, and a test pad connected with the test circuit, according to one or more embodiments, the method includes performing an Electrical Die Sorting (EDS) inspection on the silicon wafer through the test pad, and performing an array inspection on the pixel circuit through the test pad by receiving, by the test circuit, a line signal transferred through the data line, converting, by the test circuit, the line signal into a digital signal to output test data, and determining whether the pixel circuit is defective based on the test data.

The method may further include probing, by inspection equipment, the test pad prior to performing the EDS inspection and performing the array inspection.

The inspection equipment may be connected with the test pad during performing the EDS inspection and performing the array inspection.

Determining whether the pixel circuit is defective based on the test data may include transmitting the test data to the test pad, and determining, by the inspection equipment, whether the pixel circuit is defective.

### BRIEF DESCRIPTION OF THE DRAWINGS

FIG. 1 is a block diagram of an electronic device according to one or more embodiments.

FIG. 2 is schematic diagrams of an electronic device according to various embodiments.

FIG. 3 is a perspective view of an electronic device according to one or more embodiments of the present disclosure.

FIG. 4 is an exploded perspective view of an electronic device according to one or more embodiments of the present disclosure.

FIG. 5 is a cross-sectional view indicating a portion taken along the line I-I′ of FIG. 4.

FIG. 6 is a view illustrating a silicon wafer according to one or more embodiments of the present disclosure.

FIG. 7 is a block diagram of a display device according to one or more embodiments of the present disclosure.

FIG. 8 is a plan view of a display module according to one or more embodiments of the present disclosure.

FIG. 9A is a circuit diagram of a pixel according to one or more embodiments of the present disclosure.

FIG. 9B is a circuit diagram of a pixel according to one or more embodiments of the present disclosure.

FIG. 10 is a diagram indicating a partial configuration of an inspection equipment and an inspection method according to one or more embodiments of the present disclosure.

FIG. 11A is a flowchart indicating a display panel inspection method according to one or more embodiments of the present disclosure.

FIG. 11B is a flowchart indicating a display panel inspection method according to one or more embodiments of the present disclosure.

FIG. 12 is a plan view of a display module according to one or more embodiments of the present disclosure.

FIG. 13 is a plan view of a display module according to one or more embodiments of the present disclosure.

FIG. 14 is a plan view of a display module according to one or more embodiments of the present disclosure.

FIG. 15 is a plan view of a display module according to one or more embodiments of the present disclosure.

FIG. 16A is a circuit diagram of a multifunction circuit according to one or more embodiments of the present disclosure.

FIG. 16B is a circuit diagram of a multifunction circuit according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, if a first part is described as being arranged “on” a second part, this indicates that the first part is arranged at an upper side or a lower side of the second part without the limitation to the upper side thereof on the basis of the gravity direction.

Further, the phrase “in a plan view” means if an object portion is viewed from above, and the phrase “in a schematic cross-sectional view” means if a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that if an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, if a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, if a portion of a layer, a film, an area, a plate, or the like is formed on another portion, a forming direction is not limited to an upper direction but includes forming the portion on a side surface or in a lower direction. On the contrary, if a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that if an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. The terms or words used in the present specification and claims are not to be limitedly interpreted as general or dictionary meanings and should be interpreted as meanings and concepts that are consistent with aspects of the present disclosure on the basis that an inventor can be their own lexicographer to appropriately define concepts of terms to describe the embodiments in the best way.

As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

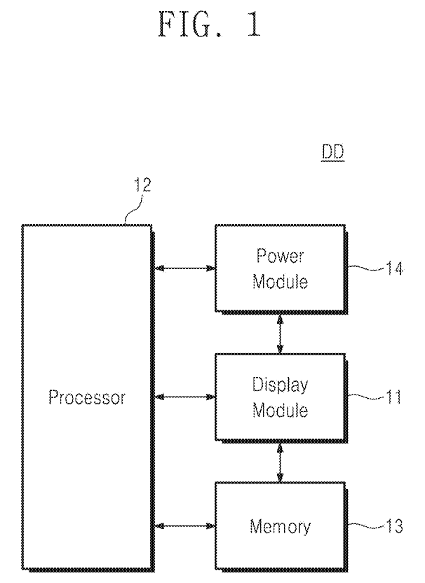

FIG. 1 is a block diagram of an electronic device according to one or more embodiments.

Referring to FIG. 1, an electronic device DD according to one or more embodiments may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), or a controller.

Data information suitable for operation of the processor 12 or the display module 11 may be stored in the memory 13. When the processor 12 executes the application stored in the memory 13, the image data signal and/or the input control signal may be transmitted to the display module 11, and the display module 11 may process the received signal to output image information through the display screen.

The power module 14 may include a power supply module, such as a power adapter or a battery device, and a power conversion module that converts power supplied by the power supply module to generate power suitable for operation of the electronic device DD.

At least one of components of the above-described electronic device DD may be included in the display device. In addition, some of the individual modules that are functionally included in one module may be included in the display device, and others may be provided separately from the display device. For example, the display device may include the display module 11, and the processor 12, the memory 13, and the power module 14 may be provided in the form of other devices in the electronic device DD other than the display device.

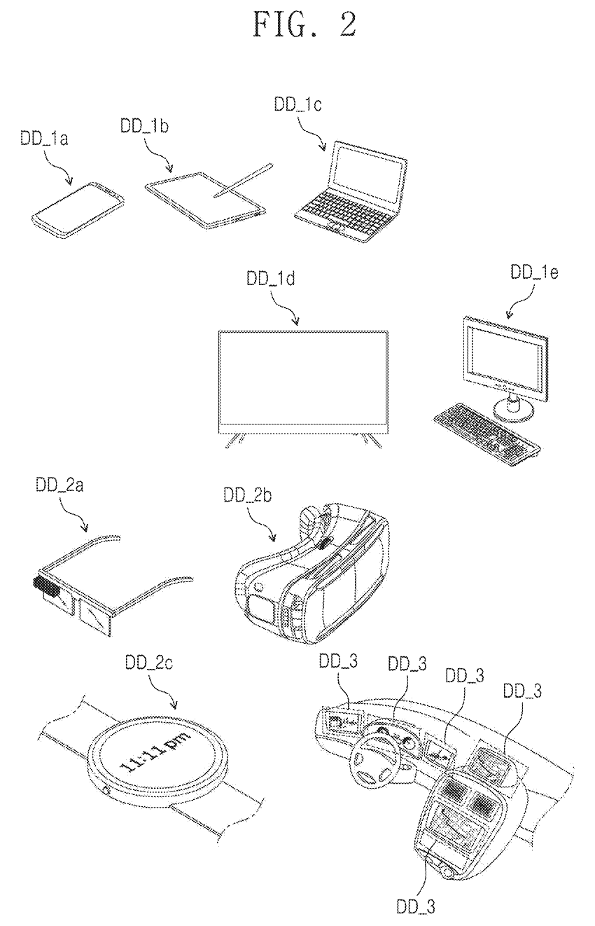

FIG. 2 is schematic diagrams of an electronic device according to various embodiments.

Referring to FIG. 2, various electronic devices to which the display device according to embodiments is applied may include not only an electronic device for image display, such as a smartphone DD_1a, a tablet PC DD_1b, a laptop DD_1c, a TV DD_1d, and a desk monitor DD_1e, but also a wearable electronic device including a display module, such as smart glasses DD_2a, a head-mounted display DD_2b, and a smart watch DD_2c, an electronic device for a vehicle DD_3 including a display module, such as a center information display (CID) and a room mirror display located on an instrument panel, a center fascia, and a dashboard of a vehicle, and/or the like.

Hereinafter, a display device and an electronic device including the display device according to one or more embodiments of the present disclosure will be described with reference to the drawings.

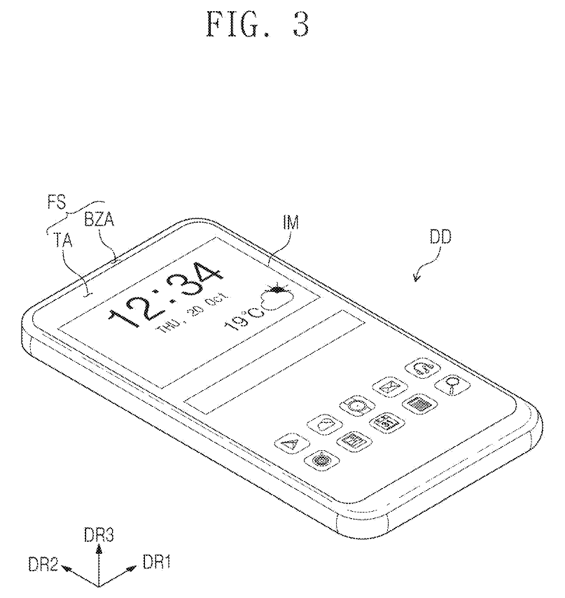

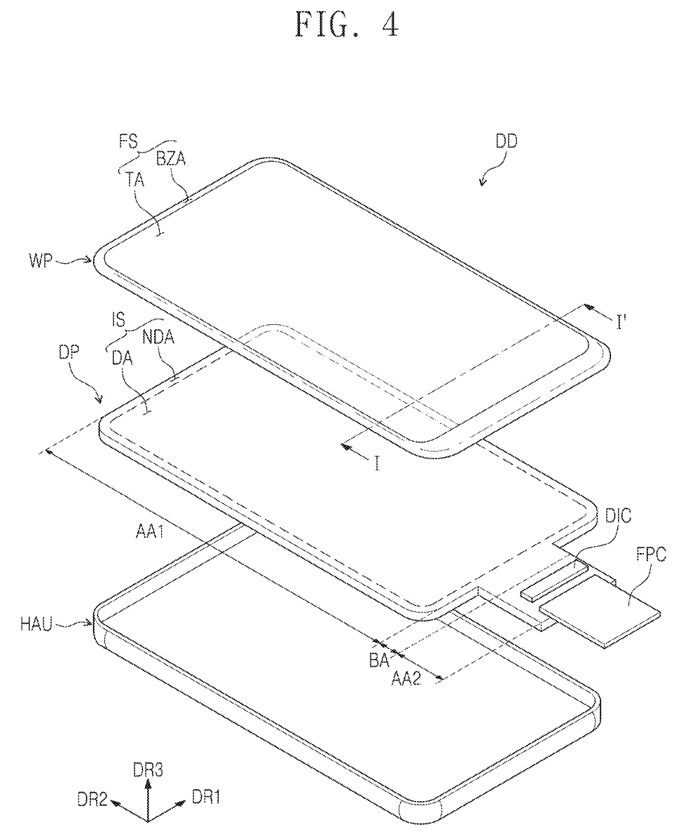

FIG. 3 is a perspective view of an electronic device DD according to one or more embodiments of the present disclosure, and FIG. 4 is an exploded perspective view of an electronic device DD according to one or more embodiments of the present disclosure.

Referring to FIGS. 3 and 4, the electronic device DD may display an image IM toward a third direction DR3 on a display surface FS parallel to each of a first direction DR1 and a second direction DR2. The image IM may include a still image as well as a dynamic image. In FIG. 3, a watch window and icons are illustrated as an example of the image IM. The display surface FS on which the image IM is displayed may correspond to a front surface of the electronic device DD.

FIGS. 3 and 4 and the following drawings illustrate the first direction DR1, the second direction DR2, and the third direction DR3, and directions indicated by the first to third directions DR1, DR2, and DR3 described in the present disclosure may be converted to other directions as a relative concept. Furthermore, directions indicated by the first to third directions DR1, DR2, and DR3 may be described as first to third directions, and the same reference numerals may be used. In the present disclosure, the first direction DR1 and the second direction DR2 may be orthogonal to each other, and the third direction DR3 may be a direction normal to a plane defined by the first direction DR1 and the second direction DR2.

A front surface (or an upper surface) and a back surface (or a lower surface) of the respective members are defined based on a direction in which the image IM is displayed. The front surface and the back surface face each other in the third direction DR3, and a normal direction of each of the front surface and the back surface may be parallel to the third direction DR3.

The electronic device DD may include a window WP, a display module DM, and a housing HAU. The window WP and the housing HAU may be coupled to each other to form an appearance of the electronic device DD.

The window WP may include an optically transparent insulating material. For example, the window WP may include glass or plastic. The front surface of the window WP may define the display surface FS of the electronic device DD. The display surface FS may include a transmission area TA and a bezel area BZA. The transmission area TA may be an optically transparent area. For example, the transmission area TA may be an area having a visible light transmittance of about 90% or more.

The bezel area BZA may be an area having a relatively low light transmittance compared to the transmission area TA. The bezel area BZA may define a shape of the transmission area TA. The bezel area BZA may be adjacent to the transmission area TA, and may surround the transmission area TA (e.g., in plan view). However, this is illustrated as an example, and the bezel area BZA of the window WP may be omitted. The window WP may include at least one functional layer of an anti-fingerprint layer, a hard coat layer, and an anti-reflection layer, and is not limited to any one embodiment.

The display module DM may have a function as an output device configured to display an image, and may have a function as an input device configured to sense an input applied from outside. The display module DM may be located under the window WP. The display module DM may be a configuration substantially generating the image IM. The image IM generated by the display module DM is displayed on a display surface IS of the display module DM and is visually recognized by a user from the outside through the transmission area TA.

The display module DM may include a display area DA and a non-display area NDA. The display area DA may be an area activated according to an electrical signal. The non-display area NDA may be adjacent to the display area DA. The non-display area NDA may surround the display area DA (e.g., in plan view). The non-display area NDA is an area covered by the bezel area BZA, and may not be visually recognized from the outside. The display area DA of the display module DM may correspond to the transmission area TA of the window WP, and the non-display area NDA of the display module DM may correspond to the bezel area BZA.

The display module DM may include a first non-bending area AA1, a bending area BA adjacent to the first non-bending area AA1, and a second non-bending area AA2 adjacent to the bending area BA. That is, the first non-bending area AA1, the bending area BA, and the second non-bending area AA2 may be defined along one direction (e.g., a direction opposite to the second direction DR2). The first non-bending area AA1 may correspond to a portion of the display area DA and the non-display area NDA, and the bending area BA and the second non-bending area AA2 may correspond to the non-display area NDA. The bending area BA may be defined between the first non-bending area AA1 and the second non-bending area AA2.

The first non-bending area AA1 may be an area in which an image IM (see FIG. 3) is displayed. The bending area BA may be an area in which a back surface of the first non-bending area AA1 and a back surface of a second non-bending area AA2 are bent to face each other. A plurality of pads may be located in the second non-bending area AA2.

A driving circuit unit DCU may be located in the second non-bending area AA2. The driving circuit unit DCU may include driving elements configured to drive pixels of the display panel DP, for example, a driving circuit DC. FIG. 4 illustrates a structure in which the driving circuit unit DCU is mounted on the display panel DP, but the present disclosure is not limited thereto. For example, the driving circuit unit DCU may be mounted on the flexible circuit board FPC. In addition, the driver circuit unit DCU may be embedded in the display panel.

The flexible circuit board FPC may be coupled to the second non-bending area AA2. The flexible circuit board FPC may be connected to the main circuit board. The main circuit board may be one electronic component constituting the electronic module.

The housing HAU may be coupled with the window WP. The housing HAU may be coupled with the window WP to provide an amount of interior space. The display module DM may be accommodated in the internal space.

The housing HAU may include a material having relatively high rigidity. For example, the housing HAU may include a plurality of frames and/or plates, including glass, plastic, or metal, or any combination thereof. The housing HAU may stably protect components of the electronic device DD accommodated in the internal space from an external impact.

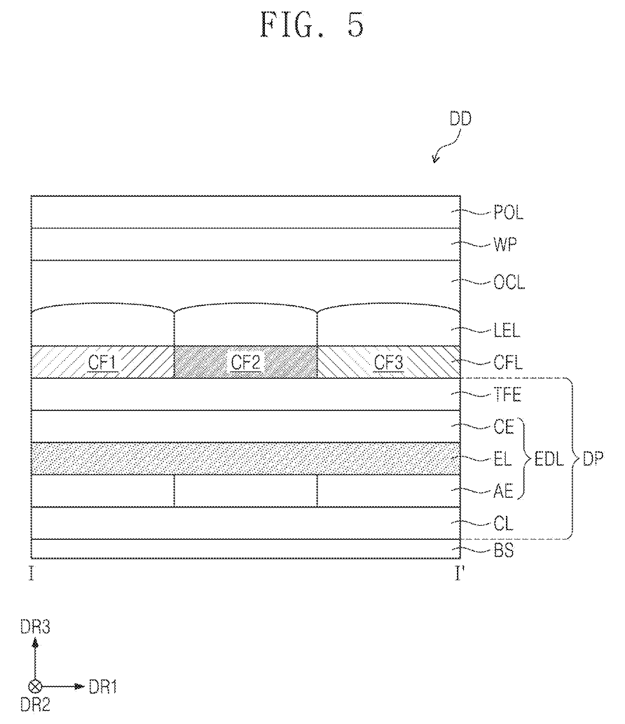

FIG. 5 is a cross-sectional view indicating a portion taken along the line I-I′ of FIG. 4.

Referring to FIGS. 4 and 5, the electronic device DD may include the display panel DP, a color filter layer CFL, a lens layer LEL, an over coat layer OCL, the window WP, and a polarizing layer POL. The display panel DP may include a circuit layer CL, a light-emitting element layer EDL, and a thin film encapsulation layer TFE.

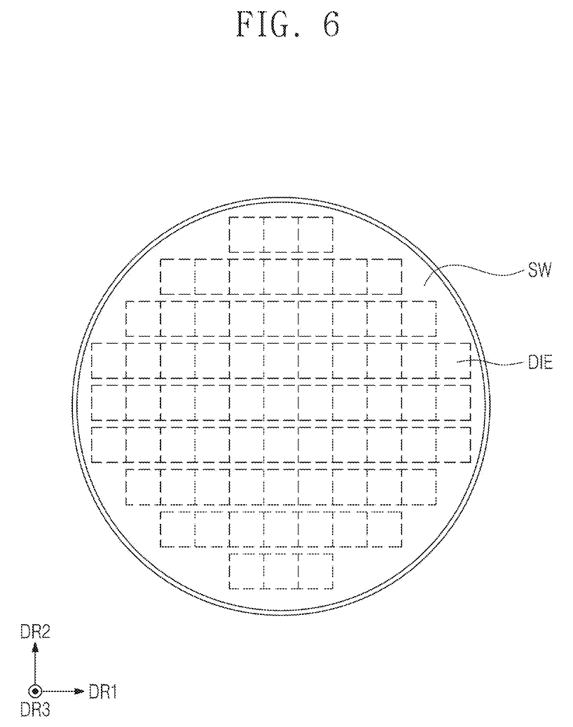

The base layer BS may provide a base surface on which the circuit layer CL is located. The base layer BS may include a silicon substrate. The base layer BS may be a portion of a silicon wafer SW (see FIG. 6). However, the present disclosure is not limited thereto, and the base layer BS may include an inorganic layer, an organic layer, or a composite material layer.

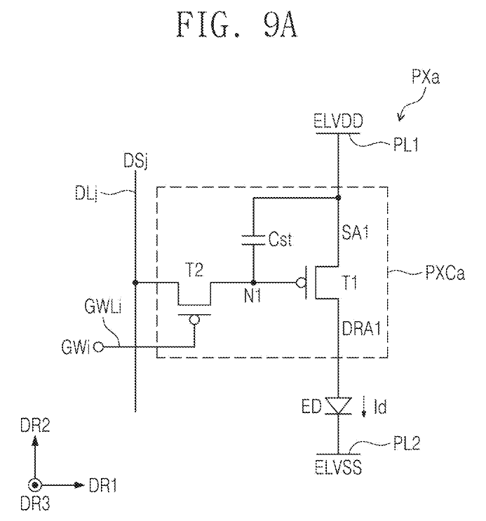

The circuit layer CL may be located above the base layer BS. Transistors constituting a data driver, a gate driver, a pixel circuit PXCa (see FIG. 9A), and/or the like may be formed in the circuit layer CL. The circuit layer CL may include at least one insulating layer, a semiconductor pattern, a conductive pattern, a signal line, and/or the like. The insulating layer, the semiconductor pattern, and the conductive pattern may be formed by coating, vapor deposition, and/or the like, and then the insulating layer, a semiconductor layer, and a conductive layer may be selectively patterned through a plurality of photolithography processes. Thereafter, the semiconductor pattern, the conductive pattern, and the signal line included in the circuit layer CL may be formed.

The light-emitting element layer EDL may be located on the circuit layer CL. The light-emitting element layer EDL may include a first electrode AE, a light-emitting layer EL, and a second electrode CE. The first electrode AE may be an anode, and the second electrode CE may be a cathode.

The first electrode AE may include a transparent conductive oxide pattern. The first electrode AE may be formed to be separated from each of the pixels. The transparent conductive oxide pattern may include indium tin oxide (ITO), indium zinc oxide (IZO), indium gallium zinc oxide (IGZO), zinc oxide (ZnOx), indium oxide (In₂O₃), or aluminum doped zinc oxide (AZO) for which hole injection is easy. The first electrode AE may have a single-layer or multi-layer structure.

The light-emitting layer EL may be located on the first electrode AE. The light-emitting layer EL may have an integral shape and may be provided in common to pixels. When the light-emitting layer EL has the integral shape, the light-emitting layer EL may provide blue light or white light. However, the present disclosure is not limited thereto, and the light-emitting layer EL may be formed to be separated from each of the pixels. When the light-emitting layer EL is formed to be separated from each of the pixels, each of the light-emitting layers EL may emit at least one of a first color light, a second color light, or a third color light. The light-emitting layer EL may include an organic light-emitting material, a quantum dot, a quantum rod, a micro LED, or a nano LED.

The second electrode CE may be located above the light-emitting layer EL. The second electrode CE may have an integral shape and may be commonly located in a plurality of pixels. A common voltage may be provided to the second electrode CE, and the second electrode CE may be referred to as a common electrode.

The thin film encapsulation layer TFE is located on the light-emitting element layer EDL. The thin film encapsulation layer TFE may protect the light-emitting element layer EDL from foreign substances, such as moisture, oxygen, and dust particles. The thin film encapsulation layer TFE may include at least one inorganic film (hereinafter, an encapsulation inorganic film). In addition, the thin film encapsulation layer TFE may further include at least one organic film (hereinafter, an encapsulation organic film). The thin film encapsulation layer TFE may include the encapsulation inorganic layer, the encapsulation organic layer, and the encapsulation inorganic layer sequentially stacked, but the layers constituting the thin film encapsulation layer TFE are not limited thereto.

The color filter layer CFL may be located on the thin film encapsulation layer TFE. The color filter layer CFL may include a plurality of color filters CF1, CF2, and CF3. The plurality of color filters CF1, CF2, and CF3 may include a first color filter CF1, a second color filter CF2, and a third color filter CF3. The first color filter CF1 may convert a color light (e.g., blue light) generated in the light-emitting layer EL into the first color light to output the first color light, and the second color filter CF2 may convert the color light generated in the light emission layer EL into the second color light to output the second color light. The third color filter CF3 may transmit the color light generated in the light-emitting layer EL to output the color light as the third color light without converting the color light. In one or more embodiments, the color filter layer CFL may further include a light-shielding pattern.

The lens layer LEL may be located on the color filter layer CFL. The lens layer LEL may include a plurality of lens patterns. The lens patterns may be located corresponding to the first to third color filters CF1, CF2, and CF3, respectively, and may be spaced apart from each other.

The over coat layer OCL may be located on the lens layer LEL. The over coat layer OCL may be optically transparent. The over coat layer OCL may comprise a planar upper surface as a planarization layer.

The window WP may be located on the over coat layer OCL. The window WP provides an outer surface of the electronic device DD.

The polarizing layer POL may be located on the window WP. The polarizing layer POL may block external light incident on the electronic device DD from the outside. The polarizing layer POL may block some of the external light. In addition, the polarizing layer POL may reduce reflected light generated in the display panel DP by the external light. That is, the polarizing layer POL may be an anti-reflection layer. For example, the polarizing layer POL may function to block the reflected light when the light incident from the outside of the electronic device DD is incident on the display panel DP and emitted again.

FIG. 6 is a view illustrating a silicon wafer SW according to one or more embodiments of the present disclosure.

Referring to FIG. 6, the silicon wafer SW may be composed of a plurality of dies DIE. For example, the silicon wafer SW may be composed of 71 dies DIE. However, this is only an example, and the number of the plurality of dies DIE is not limited thereto.

The display panel DP (see FIG. 5) may be formed on each of the plurality of dies DIE.

All or part of the display panel DP (see FIG. 5) is a kind of an integrated circuit made through a silicon wafer SW manufacturing process (semiconductor process), and may be considered as a semiconductor chip. Accordingly, all or part of the display panel DP according to embodiments of the present disclosure may be referred to as a display integrated circuit.

The display panel DP (see FIG. 5) according to the embodiments of the present disclosure has an advantage of being able to be manufactured accurately, easily, and conveniently because all or part of the display panel DP is made through the silicon wafer SW manufacturing process. However, because the display panel DP (see FIG. 5) is manufactured through the silicon wafer SW manufacturing process, a test method suitable for the display panel DP is required.

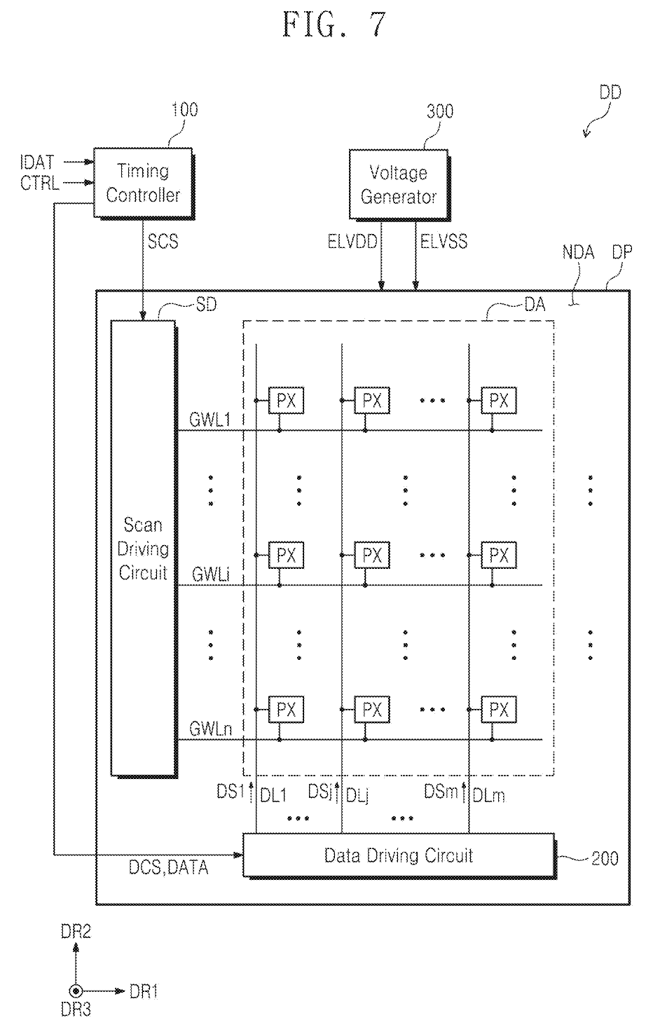

FIG. 7 is a block diagram of a display device according to one or more embodiments of the present disclosure.

Referring to FIG. 7, the electronic device DD may be activated according to the electrical signal, and may display the image IM. The electronic device DD according to one or more embodiments includes the display panel DP, a timing controller 100, and a voltage generator 300.

The display panel DP includes a plurality of scan lines GWL1-GWLn, a plurality of data lines DL1-DLm, a data-driving circuit 200, and a plurality of pixels PX. The display panel DP may further include a scan-driving circuit SD.

The timing controller 100 may receive an image signal IDAT and a control signal CTRL from an external host processor (e.g., an application processor (AP), a graphics processing unit (GPU), or a graphics card). The processor 12 (see FIG. 1) may include a host processor. In one or more embodiments, the image signal IDAT may be RGB image data including red image data, green image data, and blue image data. In one or more embodiments, the control signal CTRL may include a vertical synchronization signal, a horizontal synchronization signal, an input data enable signal, a master clock signal, and/or the like, but is not limited thereto.

The timing controller 100 may drive the display panel DP. The timing controller 100 receives the image signal IDAT and the control signal CTRL. The timing controller 100 generates an image data signal DATA obtained by converting a data format of the image signal IDAT to meet an interface specification with the data-driving circuit 200. The timing controller 100 outputs a scan control signal SCS and a data control signal DCS.

The data-driving circuit 200 receives the data control signal DCS and the image data signal DATA from the timing controller 100. The data-driving circuit 200 converts the image data signal DATA into a plurality of data signals DS1-DSm, and outputs the plurality of data signals DS1-DSm to the plurality of data lines DL1-DLm to be described later. The plurality of data signals DS1-DSm are analog voltages corresponding to a gradation value of the image data signal DATA.

The voltage generator 300 generates voltages suitable for operation of the display panel DP. The voltage generator 300 generates a first driving voltage ELVDD and a second driving voltage ELVSS.

The display panel DP according to one or more embodiments of the present disclosure may be a light-emitting display panel, and is not particularly limited. For example, the display panel DP may be an organic light-emitting display panel, an inorganic light-emitting display panel, a micro LED display panel, or a nano LED display panel. The light-emitting layer of the organic light-emitting display panel may include the organic light-emitting material. The light-emitting layer of the inorganic light-emitting display panel may include the quantum dot, the quantum rod, and/or the like. The light-emitting layer of the micro LED display panel may include the micro LED. The light-emitting layer of the nano LED display panel may include the nano LED.

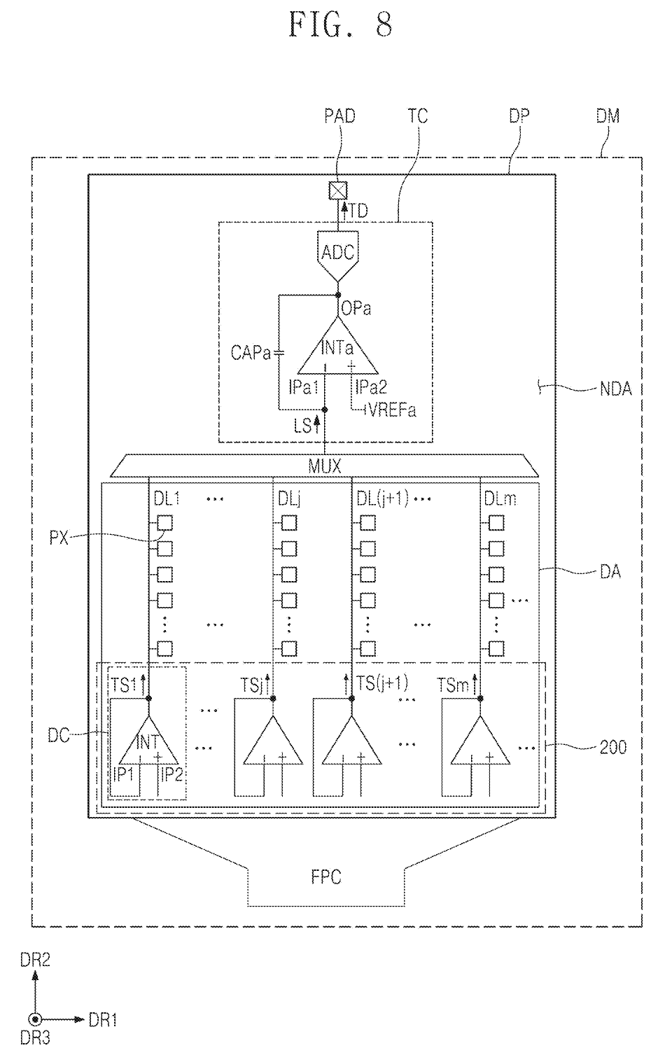

In the display panel DP, the display area DA and the non-display area NDA around the display area DA may be defined. The display area DA and the non-display area NDA may be distinguished depending on whether the plurality of pixels PX is arranged. The plurality of pixels PX and the data-driving circuit 200 may be located in the display area DA. The data-driving circuit 200 may include a plurality of driving circuits DC (see FIG. 8). The scan-driving circuit SD may be located in the non-display area NDA.

In one or more embodiments, the scan-driving circuit SD is arranged on one side of the display panel DP. The scan lines GWL1-GWLn extend from the scan-driving circuit SD in the first direction DR1.

The plurality of pixels PX may be electrically connected to the scan lines GWL1-GWLn and the plurality of data lines DL1-DLm, respectively.

Each of the plurality of pixels PX may receive the first driving voltage ELVDD and the second driving voltage ELVSS from the voltage generator 300.

The scan-driving circuit SD receives the scan control signal SCS from the timing controller 100. The scan-driving circuit SD may output scan signals to the scan lines GWL1-GWLn in response to the scan control signal SCS.

FIG. 8 is a plan view of a display module DM according to one or more embodiments of the present disclosure.

In describing FIG. 8, components described with reference to FIG. 7 are denoted by the same reference numerals, and description thereof is omitted.

Referring to FIG. 8, the display module DM may include the display panel DP, and the flexible circuit board FPC electrically connected to the display panel DP.

The display panel DP may further include a multiplexer MUX, a test circuit TC, and a test pad PAD. The multiplexer MUX, the test circuit TC, and the test pad PAD may be located in the non-display area NDA.

The plurality of pixels PX may be arranged in the first direction DR1 and the second direction DR2. In the plurality of pixels PX, a plurality of pixel rows extending in the first direction DR1 and arranged in the second direction DR2, and a plurality of pixel columns extending in the second direction DR2 and arranged in the first direction DR1, may be defined.

The plurality of data lines DL1-DLm may be electrically connected to the plurality of pixels PX. The data-driving circuit 200 may be located at a lower end of the display panel DP. For example, the data-driving circuit 200 may be adjacent to the flexible circuit board FPC.

The data-driving circuit 200 may include a timing controller that outputs a timing signal, and the plurality of driving circuits DC that respectively provide a plurality of test signals TS1-TSm to the plurality of data lines DL1-DLm based on the timing signal.

Each of the plurality of driving circuits DC may include an operational amplifier INT. The operational amplifier INT may be configured in the form of a voltage follower to apply an output of a digital-to-analog converter to the corresponding plurality of data lines DL1-DLm.

For example, the operational amplifier INT may be configured with an inverted terminal IP1, a non-inverted terminal IP2, and an output terminal OP. The inverted terminal IP1 of the operational amplifier INT may be connected with the output terminal OP, and the non-inverted terminal IP2 may be connected with the timing controller 100 (see FIG. 7). The non-inverted terminal IP2 may receive a signal configured to test from the timing controller 100 (see FIG. 7). The plurality of driving circuits DC may output the plurality of test signals TS1-TSm through the plurality of data lines DL1-DLm.

The multiplexer MUX, the test circuit TC, and the test pad PAD may be located at an upper end of the display panel DP.

The multiplexer MUX may be connected with the plurality of pixels PX. A plurality of input terminals of the multiplexer MUX may correspond to, and may be connected to, the plurality of data lines DL1-DLm, respectively. At least one output terminal of the multiplexer MUX may select at least one data line from among the plurality of data lines DL1-DLm. In FIG. 8, the multiplexer MUX having one output terminal is described.

The multiplexer MUX may receive the plurality of test signals TS1-TSm through the plurality of input terminals, respectively, and may select at least one of the test signals TA1-TSm to output a line signal LS through the output terminal. For example, the line signal LS may be the at least one of the test signals TS1-TSm.

The test circuit TC may be connected to the output terminal of the multiplexer MUX. The test circuit TC may include an operational amplifier INTa, a capacitor CAPa, and an analog-to-digital converter ADC.

The operational amplifier INTa may receive a first voltage value of the line signal LS, which is an analog signal, and may amplify the first voltage value to a second voltage value having a voltage level that is higher than the first voltage value. The operational amplifier INTa may operate as an integrator. In this case, the operational amplifier INTa and the capacitor CAPa may be referred to as the integrator.

The operational amplifier INTa may include an inverted terminal IPa1, a non-inverted terminal IPa2, and an output terminal OPa. The inverted terminal IPa1 is connected to the output terminal of the multiplexer MUX, and may receive the line signal LS. A reference voltage VREFa may be input to the non-inverted terminal IPa2. The operational amplifier INTa may integrate and output the line signal LS input to the inverted terminal IPa1 based on the fixed reference voltage VREFa. When the reference voltage VREFa is not about 0 V, the output of the operational amplifier INTa may be changed based on the reference voltage VREFa. The inverted terminal IPa1 may be connected to the output terminal OPa, and the capacitor CAPa may be connected therebetween.

The analog-to-digital converter ADC may convert the second voltage value into a digital signal to generate test data TD, and may output the test data TD to the test pad PAD.

The test pad PAD is connected with the test circuit TC, and may output the test data TD to the outside.

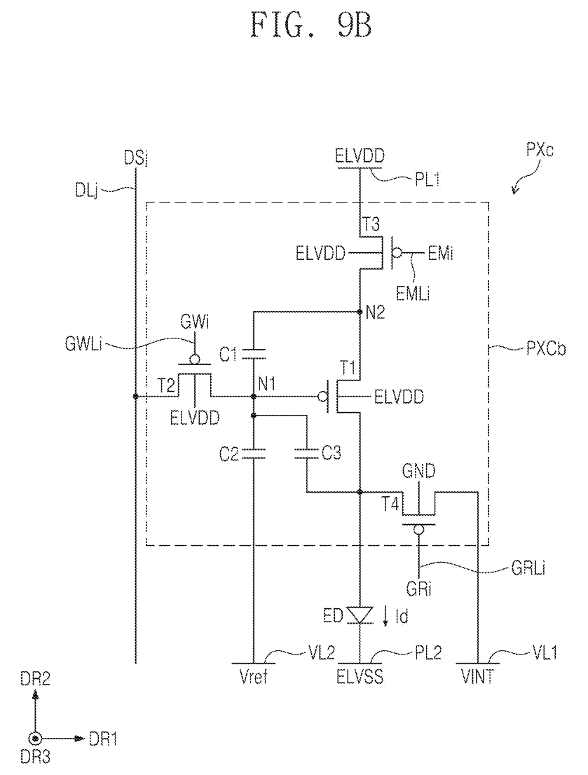

The test pad PAD may be connected to an external inspection equipment IE (see FIG. 10). The test pad PAD may output the test data TD to the inspection equipment IE (see FIG. 10). When an external pressure is applied, the test pad PAD may leave a trace externally. According to the present disclosure, the inspection history may be determined by checking the trace remaining on the test pad PAD. That is, it is possible to check whether the previous inspection is performed, thereby avoiding unnecessary duplicate inspections. Thus, the efficiency and reliability of the manufacturing process may be improved.

The data-driving circuit 200, the plurality of data lines DL1-DLm, the multiplexer MUX, the test circuit TC, and the test pad PAD may be located in the circuit layer CL (see FIG. 5). The Electrical Die Sorting (EDS) inspection and array inspection, which will be described later, may be performed after the circuit layer CL (see FIG. 5) is formed.

FIG. 9A is a circuit diagram of a pixel according to one or more embodiments of the present disclosure.

Referring to FIGS. 7, 8, and 9A, FIG. 9A illustrates a pixel PXa including a pixel circuit PXCa, and a light-emitting element ED electrically connected to the pixel circuit PXCa. The pixel PXa of FIG. 9A may refer to one pixel among the plurality of pixels PX of FIG. 8.

In FIG. 9A, the pixel circuit PXCa may include two transistors (first and second transistors T1 and T2) and one capacitor Cst. Each of the first transistor T1 and the second transistor T2 may be a transistor having a low-temperature polycrystalline silicon (LTPS) semiconductor layer. As an example of the present disclosure, the first and second transistors T1, T2 may be P-type transistors.

The pixel PXa may be connected to an i-th write scan line GWLi among the plurality of write scan lines, and may be connected to a j-th data line DLj among the plurality of data lines DL1-DLm. The i-th write scan line GWLi may transmit the i-th write scan signal GWi to the pixel PXa, and the j-th data line DLj may transmit the j-th data signal DSj to the pixel PXa. The j-th data signal DSj may be output from the data-driving circuit 200.

The pixel PXa may be connected with a first power line PL1 that receives the first driving voltage ELVDD and a second power line PL2 that receives the second driving voltage ELVSS. In here, the first driving voltage ELVDD may have a higher voltage level than the second driving voltage ELVSS.

The light-emitting element ED may include an anode and a cathode. When the light-emitting device is an organic light-emitting device, the light-emitting device may further include an organic layer located between the anode and the cathode. The anode of the light-emitting element ED may be connected to the pixel circuit PXCa. The cathode of the light-emitting element ED may be connected to the second power line PL2. The light-emitting element ED may emit light corresponding to an amount of current flowing through the first transistor T1 of the pixel circuit PXCa.

The first transistor T1 is connected between the first power line PL1, which receives the first driving voltage ELVDD, and the anode of the light-emitting element ED. The first transistor T1 may be referred to as a driving transistor. The first transistor T1 may include a first electrode, a second electrode, and a gate electrode. The gate electrode is connected to a first node N1, the first electrode is electrically connected to the first power line PL1, and the second electrode may be connected to the anode of the light-emitting element ED. The first electrode may be referred to as a source area SA1 of the first transistor T1, and the second electrode may be referred as a drain area DRA1 of the first transistor T1. The first transistor T1 may receive thej-th data signal DSj transmitted by the j-th data line DLj according to a switching operation of the second transistor T2 to supply a driving current Id to the light-emitting element ED.

In FIG. 9A, when the first transistor T1 is a P-type transistor, the source area SA1 of the first transistor T1 may be electrically connected to the first power line PL1, and the drain area DRA1 of the first semiconductor transistor T1 may be electrically connected to the anode of the light-emitting element ED.

However, the present disclosure is not limited thereto, and as shown in FIG. 9B, when the first transistor T1 is a P-type transistor, a third transistor T3 (see FIG. 9B) for light emission control may be further located between the source area SA1 of the first transistor T1 and the first power line PL1. In addition, in one or more embodiments, when the first transistor is an N-type transistor, a transistor for light emission control may be further located between the source area of the first transistor and the anode of the light-emitting element.

The second transistor T2 is connected between the j-th data line DLj and the first node N1, and receives the i-th write scan signal GWi. The second transistor T2 may be referred to as a switching transistor. The second transistor T2 may include a first electrode connected to the j-th data line DLj, a second electrode connected to the first node N1, and a gate electrode connected to the i-th write scan line GWLi. The second transistor T2 may be turned on by the i-th write scan signal GWi received through the i-th write scan line GWLi to transmit the j-th data signal DSj transmitted from thej-th data line DLj to the first node N1.

The capacitor Cst may be connected between the first power line PL1 that provides the first driving voltage ELVDD and the first node N1. The capacitor Cst may include a first electrode connected to the first power line PL1 and a second electrode connected to the first node N1. The capacitor Cst may store a differential voltage between the first power line PL1 and the first node N1.

According to the present disclosure, the display panel DP may include the test circuit TC and the test pad PAD. In an inspection operation of the display panel, the EDS inspection and the array inspection may be performed in one inspection equipment (IE). The EDS inspection and the array inspection may be performed in a state where only the pixel circuit PXCa is formed. For example, the EDS inspection and the array inspection may be performed in a state where the light-emitting element ED is not formed. The inspection equipment IE may be connected with the test pad PAD. In the array inspection, a MOS characteristics of the first transistor T1 may be inspected. The data signal DSj transmitted through the j-th data line DLj may be charge-transferred by the capacitor Cst to be converted into the line signal LS. The line signal LS may be transmitted to the test pad PAD as the test data TD through the operational amplifier INT and the analog-to-digital converter ADC in the test circuit TC. The inspection equipment IE may receive the test data TD by probing the test pad PAD. The inspection equipment IE may determine whether the plurality of pixels PX is normal by using the test data TD. Thus, electrical inspection operations may be simplified, process efficiency may be improved, and productivity may be increased.

FIG. 9B is a circuit diagram of a pixel according to one or more embodiments of the present disclosure.

Referring to FIGS. 8 and 9B, FIG. 9B illustrates a pixel PXc including a pixel circuit PXCb, and a light-emitting element ED electrically connected to the pixel circuit PXCb. The pixel circuit PXCb may include four transistors (first to fourth transistors T1, T2, T3, and T4) and three capacitors (first to third capacitors C1, C2, and C3). Each of the first to fourth transistors T1 to T4 may be a transistor having an LTPS semiconductor layer. As an example of the present disclosure, some of the first to fourth transistors T1 to T4 may be P-type transistors, and the others may be N-type transistors. For example, among the first to fourth transistors T1 to T4, the first to third transistors T1 and T3 may be P-type transistors, and the fourth transistor T4 may be an N-type transistor having an oxide semiconductor as a semiconductor layer. As another example, all of the first to fourth resistors T1 to T4 may be P-type transistors, or all of the first and fourth transistors T1-T4 may be N-type transistors.

The first transistor T1 is electrically connected between the first power line PL1, which receives the first driving voltage ELVDD, and the anode of the light-emitting element ED. The first transistor T1 may be referred to as a driving transistor. The first transistor T1 may include a first electrode, a second electrode, and a gate electrode. The gate electrode may be connected to the first node N1, the first electrode may be connected to a second node N2, and the second electrode may be connected to the anode of the light-emitting element ED. The first electrode may be referred to as a source of the first transistor T1, and the second electrode may be referred as a drain of the first transistor T1. The first transistor T1 may receive thej-th data signal DSj transmitted by the j-th data line DLj according to the switching operation of the second transistor T2 to supply the driving current Id to the light-emitting element ED.

The second transistor T2 is connected between thej-th data line DLj and the first node N1, and receives thei-th write scan signal GWi. The second transistor T2 may be referred to as a switching transistor. The second transistor T2 may include a first electrode connected to the j-th data line DLj, a second electrode connected to the first node N1, and a gate electrode connected to thei-th write scan line GWLi. The second transistor T2 may be turned on by the i-th write scan signal GWi received through the i-th write scan line GWLi to transmit the j-th data signal DSj transmitted from the j-th data line DLj to the first node N1.

The third transistor T3 is connected between the first power line PL1 and the second node N2, and receives the i-th light emission control signal EMi. The third transistor T3 may be turned on according to the i-th light emission control signal EMi received through the light emission control line EMLi. The first driving voltage ELVDD applied through the turned-on third transistor T3 may be transmitted to the light-emitting element ED through the first transistor T1.

The fourth transistor T4 is connected between a first voltage line VL1 that provides an initialization voltage VINT and the anode of the light-emitting element ED, and may receive ani-th reset scan signal GRi. The fourth transistor T4 may be turned on by the i-th reset scan signal GRi received through the i-th reset scan line GRLi to transmit the initialization voltage VINT to the second electrode of the first transistor T1.

As an example of the present disclosure, each of the first to fourth transistors T1 to T4 may further include a third electrode. As illustrated in FIG. 9B, the third electrodes of the first to third transistors T1 to T3 may receive the first driving voltage ELVDD, and the third electrode of the fourth transistor T4 may receive a ground voltage GND.

The first capacitor C1 may be connected between the first node N1 and the second node N2. The first capacitor C1 may store a differential voltage between the first node N1 and the second node N2.

The second capacitor C2 may be connected between the first node N1 and a second voltage line VL2 that provides a reference voltage Vref. The second capacitor C2 may store a differential voltage between the first node N1 and the second voltage line VL2.

The third capacitor C3 may be electrically connected between the first node N1 and the first voltage line VL1 that provides the initialization voltage VINT. The third capacitor C3 may store a differential voltage between the first node N1 and the first voltage line VL1.

However, the present disclosure is not limited thereto. In addition to the configurations of the pixel circuits PXCa and PXCb of FIGS. 9A and 9B, the number of transistors or the number of capacitors may be variously changed according to the design of the pixel circuit.

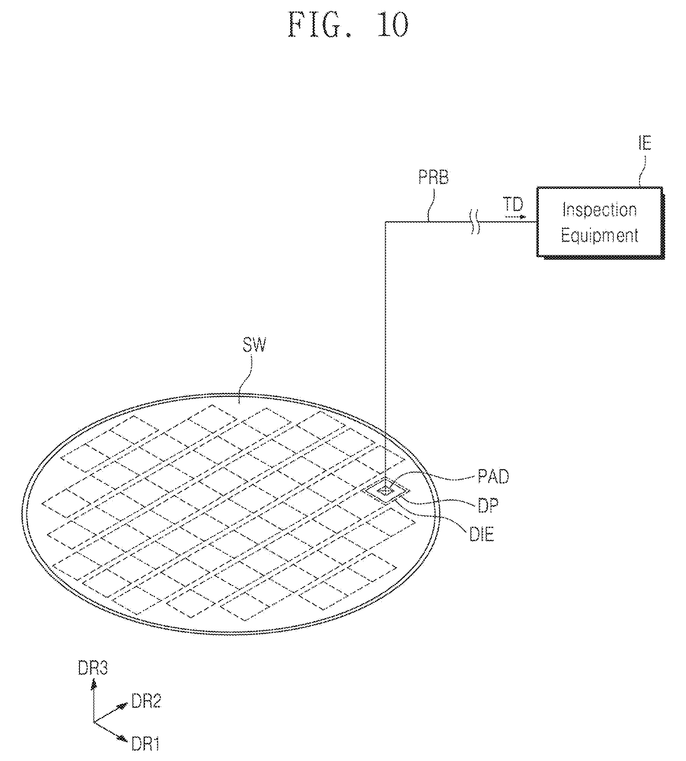

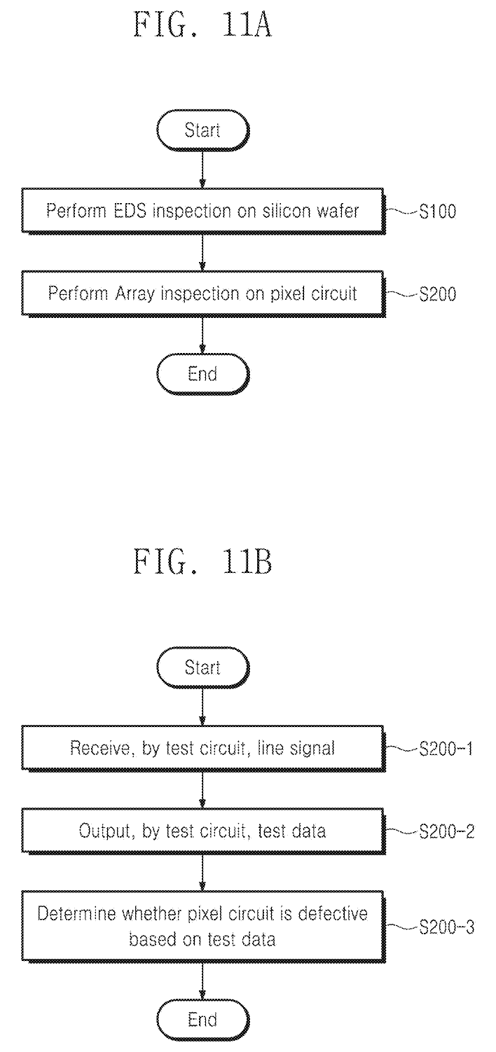

FIG. 10 is a diagram indicating a partial configuration of an inspection equipment IE and an inspection method according to one or more embodiments of the present disclosure. FIGS. 11A and 11B are flowcharts indicating a display panel inspection method according to one or more embodiments of the present disclosure.

Referring to FIGS. 8, 10, 11A, and 11B, the inspection operation of the display panel may perform the EDS inspection and the array inspection in one inspection equipment IE.

The inspection operation of the display panel may include an operation S100 of performing the EDS (Electrical Die Sorting) inspection on the silicon wafer SW through the test pad PAD, and an operation S200 of performing the array inspection on the pixel circuits PXCa and PXCb (see FIGS. 9A and 9B) through the test pad PAD.

The inspection operation of the display panel may further include an operation of probing the test pad PAD by the inspection equipment IE before the operation S100 of performing the EDS inspection on the silicon wafer SW through the test pad PAD, and the operation S200 of performing the array inspection on the pixel circuit through the test pad PAD.

In the operation S100 of performing the EDS inspection on the silicon wafer SW through the test pad PAD, the inspection equipment IE may be connected with the test pad PAD through a probe PRB. The inspection equipment IE may select goodness of the product (wafer, die, etc.). The inspection equipment IE may inspect an electrical characteristic(s) of a circuit embedded in the display panel DP configured in each die DIE constituting the silicon wafer SW through the probe PRB connected with the test pad PAD. For example, the EDS inspection operation may inspect the scan-driving circuit SD (see FIG. 7), the timing controller 100 (see FIG. 7), and/or the like.

The probe PRB may include a plurality of needles contacting the test pad PAD of each chip to apply an electrical signal for electrical inspection of the die DIE constituting the silicon wafer SW.

The inspection equipment IE may apply the electrical signal to the die DIE constituting the silicon wafer SW using the probe PRB, and may determine whether the die DIE is defective through a signal generated by the applied electrical signal. As a result of the EDS inspection using the probe PRB, the die DIE determined to be good may be manufactured into a product through a subsequent process, such as packaging.

During the operation S100 of performing the EDS (Electrical Die Sorting) inspection on the silicon wafer SW, the inspection equipment IE may be connected to the test pad PAD.

During the operation S200 of performing the array inspection on the pixel circuits PXCa and PXCb (see FIGS. 9A and 9B), the inspection equipment IE may be connected to the test pad PAD. That is, after the operation S100 of performing the EDS (Electrical Die Sorting) inspection, the probe PRB may proceed to the operation S200 of performing the array inspection without separate movement.

The operation S200 of performing the array inspection on the pixel circuit through the test pad PAD may include an operation S200-1 of receiving, by the test circuit TC, the line signal LS transferred through the plurality of data lines DL1-DLm, an operation S200-2 of converting, by the test circuit TC, the line signal LS into the digital signal to output the test data TD, and an operation S200-3 of determining whether the pixel circuits PXCa and/or PXCb (see FIGS. 9A and 9B) are defective based on the test data TD.

The operation S200-3 of determining whether the pixel circuits PXCa and PXCb (see FIGS. 9A and 9B) are defective based on the test data TD may include an operation of transmitting the test data TD to the test pad PAD, and an operation of determining, by the inspection equipment IE, whether the pixel circuits (see PXCa, PXCb, and FIGS. 9A and 9B) are defective.

Unlike the present disclosure, the inspection operation of the display panel may include an EDS inspection operation and an array inspection operation, each using a separate inspection apparatus. However, because fine charge measurement is difficult in the EDS inspection operation and inspection of the display area DA including the plurality of pixels PX is not possible, it is separately inspected whether the pixel PX is abnormal in the array inspection operation. In the array inspection operation, a very fine charge is made to flow through the array equipment, and the charge transfer is measured after a certain period of time to determine whether the pixel PX operates normally. The inspection time may be delayed as using the separate inspection apparatus for each inspection.

However, according to the present disclosure, the display panel DP may include the test circuit TC and the test pad PAD. The operational amplifier INTa and the analog-to-digital converter ADC included in the test circuit TC may be internalized in the display panel DP. The operational amplifier INTa may operate as the integrator to amplify the fine charge so as to be measurable. In the inspection operation of the display panel, the EDS inspection and the array inspection may be performed in one inspection equipment (IE). The inspection equipment IE may be connected to the test pad PAD through the probe PRB. Thus, electrical inspection operations may be simplified, process efficiency may be improved, and productivity may be increased. In the array inspection, the display panel DP may output a digital bit output from the test pad PAD to the inspection equipment IE and the inspection equipment IE may determine whether the plurality of pixels PX is normal. The abnormal pixel may be corrected in a subsequent repair operation by recording the position of the pixel in x and y coordinates.

The inspection equipment IE may perform an additional inspection on the silicon wafer SW after deposition. The additional inspection may include a wafer level visual inspection (WVI), a repair, an array visual repair (AVR) operation. After the additional inspection is completed, a module process may proceed. The module process may be a process of manufacturing the display module DM. The flexible circuit board FPC may be assembled to the display panel DP through the module process.

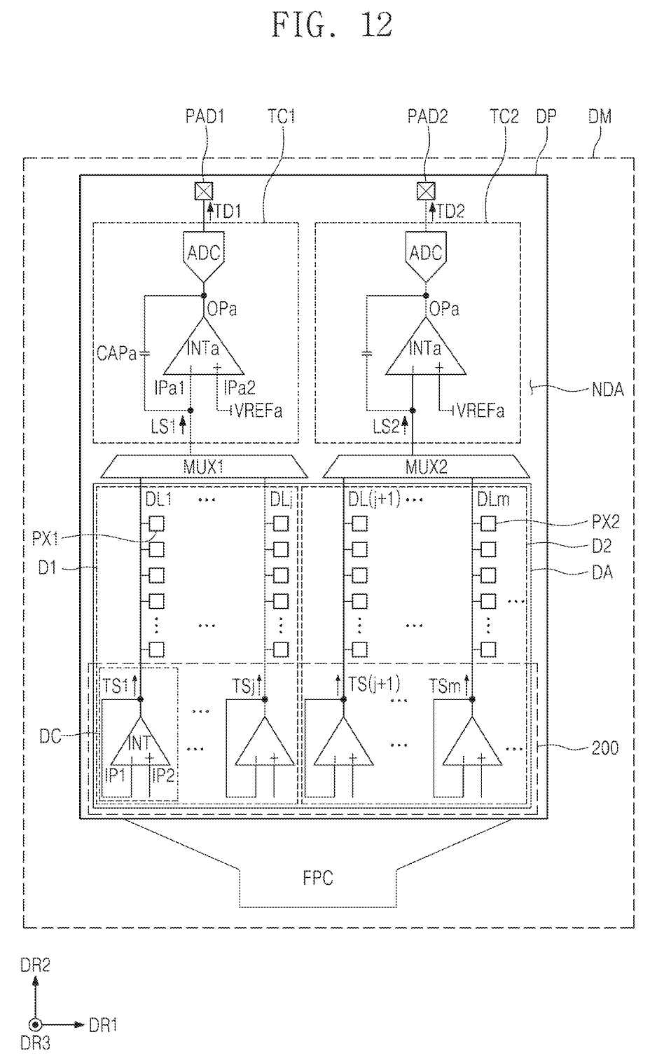

FIG. 12 is a plan view of a display module according to one or more embodiments of the present disclosure. In describing FIG. 12, components described with reference to FIG. 8 are denoted by the same reference numerals, and description thereof is omitted.

The multiplexer may be provided in plural. For example, the plurality of multiplexers MUX1 and MUX2 may include a first multiplexer MUX1 and a second multiplexer MUX2.

The plurality of pixels PX may include a first pixel PX1 and a second pixel PX2. In the display area DA, a first area D1 including the first pixel PX1, and a second area D2 including the second pixel PX2, may be defined. The first area D1 and the second area D2 may be spaced apart in the first direction DR1.

In the display area DA, a plurality of areas of a first area and a second area to an n-th area may be defined. In this case, n may be a natural number of 3 or more. The plurality of areas may include the same number of pixel columns. For example, when only one area is defined in the display area DA, the one area may include 126 pixel columns. When the first area D1 and the second area D2 are defined, each of the first and second areas D1 and D2 may include 63 pixel columns. However, this is only an example, and the number of pixel columns corresponding to the plurality of areas is not limited thereto.

When the first area D1 and the second area D2 are defined in the display area DA, the plurality of pixels PX including the first pixel PX1 defined in the first area D1 may be connected with the first multiplexer MUX1, and the plurality of pixels PX including the second pixel PX2 defined in the second area D2 may be connected with the second multiplexer MUX2.

The plurality of test circuits TC1 and TC2 may correspond to the plurality of multiplexers MUX1 and MUX2, respectively. For example, the plurality of test circuits TC1 and TC2 may include a first test circuit TC1 and a second test circuit TC2. The first test circuit TC1 may be connected with the first multiplexer MUX1, and the second test circuit TC2 may be connected with the second multiplexer MUX2. The first multiplexer MUX1 may output the line signal LS1 to the first test circuit TC1. The second multiplexer MUX2 may output the line signal LS2 to the second test circuit TC2.

According to the present disclosure, as the plurality of test circuits TC1 and TC2 is provided, the display panel DP may transmit information of the display panel DP to the inspection equipment IE more quickly. Therefore, not only the efficiency of the inspection process may be improved, but also a time reduction and a cost reduction effect in a logistics process may be expected.

The test pad PAD may be provided in plural. The plurality of test pads PAD may correspond to a plurality of test circuits TC, respectively. For example, the test pads PAD may include a first test pad PAD1 and a second test pad PAD2. The first test pad PAD1 may be connected with the first test circuit TC1, and the second test pad PAD2 may be connected with the second test circuit TC2. The first test circuit TC1 may output the test data TD1 to the first test pad PAD1. The second test circuit TC2 may output the test data TD2 to the second test pad PAD2.

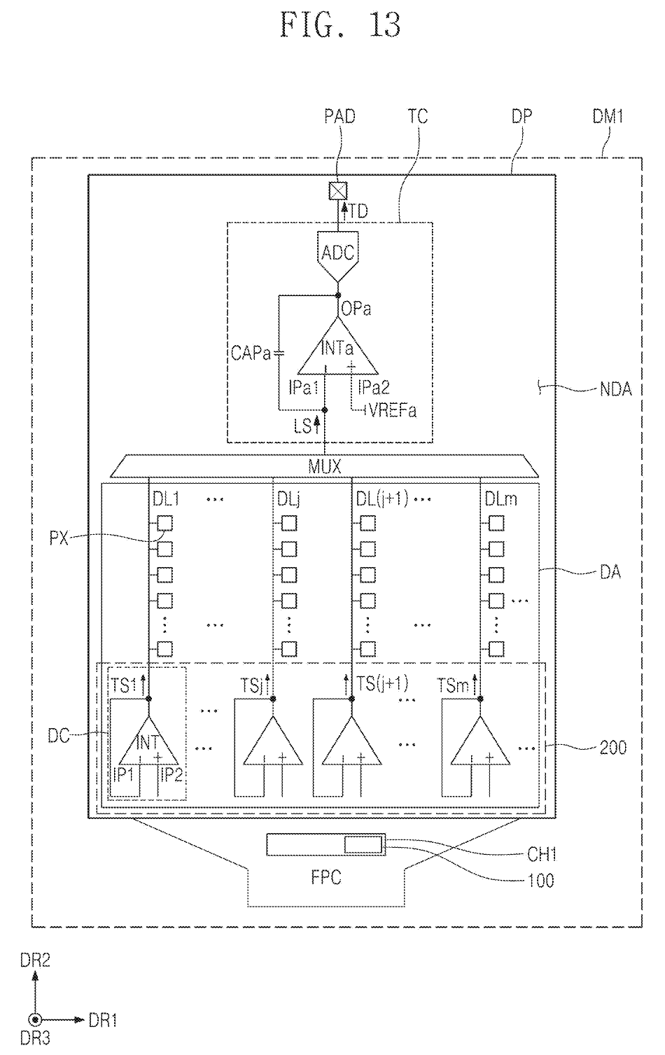

FIG. 13 is a plan view of a display module according to one or more embodiments of the present disclosure. In describing FIG. 13, components described with reference to FIGS. 7-9B and 12 are denoted by the same reference numerals, and description thereof is omitted.

Referring to FIG. 13, the display module DM1 may further include a first chip CH1 located on the flexible circuit board FPC.

The first chip CH1 may include the timing controller 100 that outputs the timing signal.

The display panel DP may include the data-driving circuit 200. The data-driving circuit 200 may include the plurality of driving circuits DC. Each of the plurality of driving circuits DC may provide the plurality of test signals TS1-TSm to the plurality of data lines DL1-DLm based on the timing signal.

When compared with FIG. 7, the timing controller 100 may be omitted in the display panel DP of FIG. 13. In this case, the timing controller 100 may be provided by the separate first chip CH1 mounted on the flexible circuit board FPC.

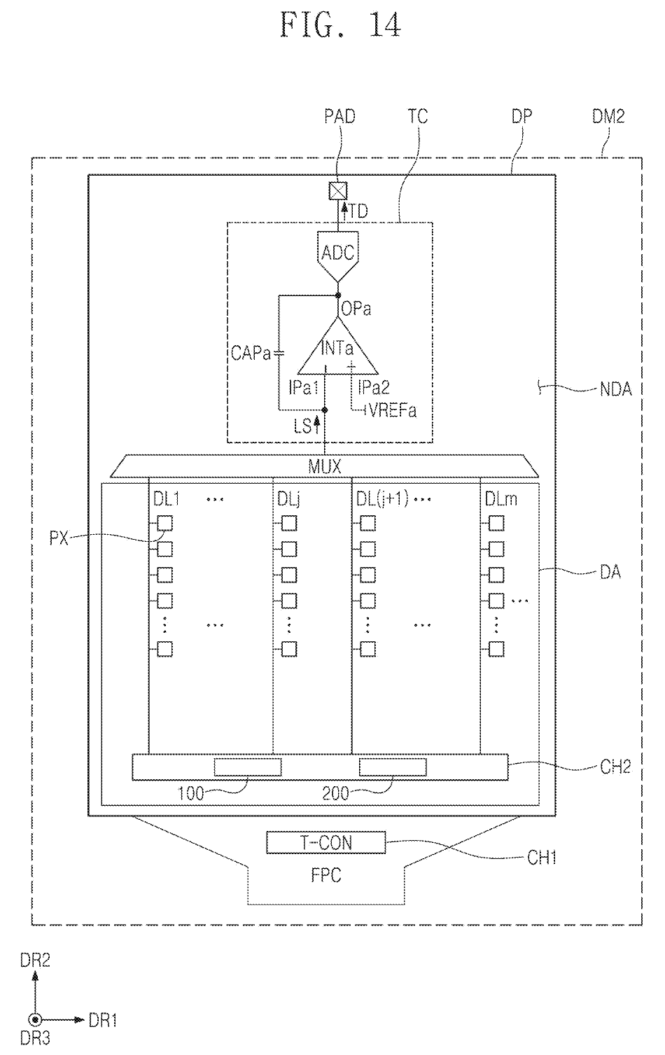

FIG. 14 is a plan view of a display module according to one or more embodiments of the present disclosure. In describing FIG. 14, components described with reference to FIGS. 7-9B and 12 are denoted by the same reference numerals, and description thereof is omitted.

Referring to FIG. 14, the display module DM2 may further include a second chip CH2 mounted on the display panel DP.

The second chip CH2 may include the timing controller 100 that outputs the timing signal and the data-driving circuit 200 that provides the timing controller 100 with the plurality of data lines DL1-DLm based on the timing signal. The second chip CH2 is mounted on the lower end of the display panel DP.

Compared with FIG. 7, in FIG. 14, the timing controller 100 and the data-driving circuit 200 may be provided through the separate second chip CH2 mounted on the display panel DP.

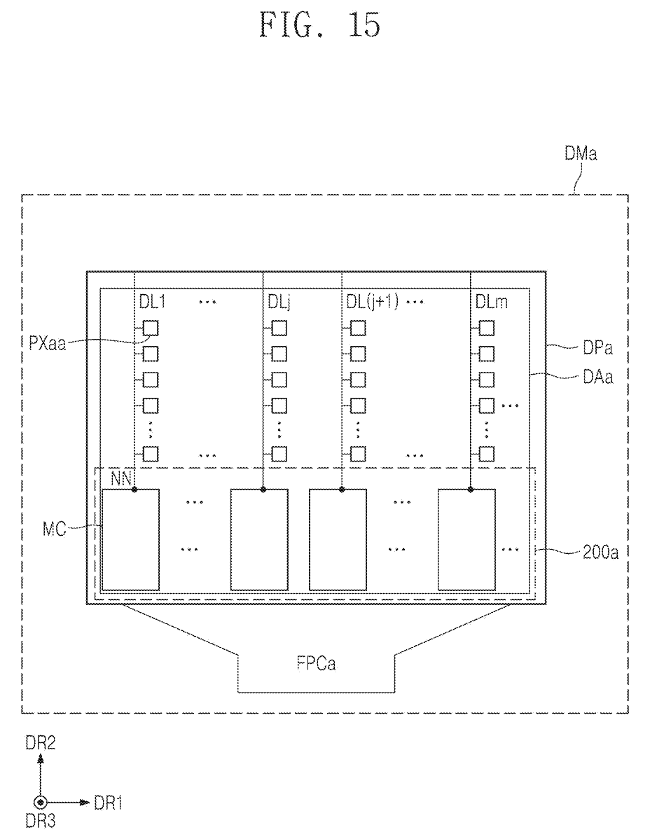

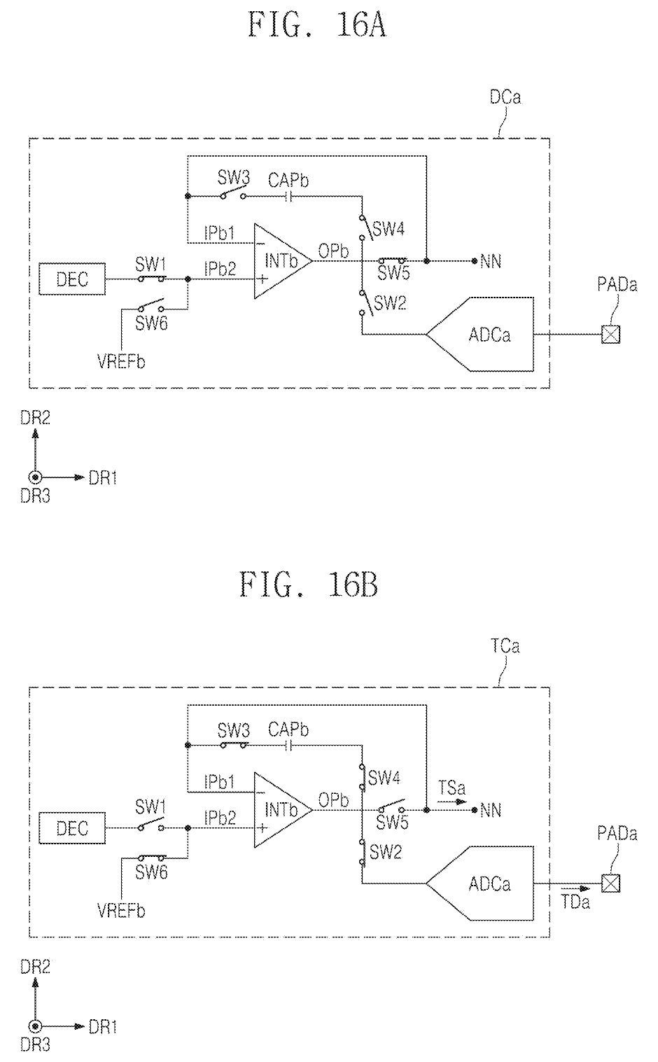

FIG. 15 is a plan view of a display module according to one or more embodiments of the present disclosure. FIGS. 16A and 16B are circuit diagrams of a multifunction circuit according to one or more embodiments of the present disclosure.

In describing FIGS. 15-16B, components described with reference to FIGS. 8 and 12 are denoted by the same reference numerals, and description thereof is omitted.

Referring to FIGS. 15 - 16B, a display module DMa may include a display panel DPa and a flexible circuit board FPCa. The display panel DPa may include a plurality of pixels PXaa, a plurality of data lines DL1-DLm, and a data-driving circuit 200a. The data-driving circuit 200a may include a plurality of multifunctional circuits MC.

A display area DAa may be defined in the display panel DPa. The pixel PXaa and the plurality of multifunction circuits MC may be located in the display area DAa. The plurality of data lines DL1-DLm and the plurality of multifunction circuits MC may be respectively connected to an input node NN.

Each of the plurality of multifunction circuits MC may include a decoder DEC, a plurality of switches SW1-SW6, an operational amplifier INTb, and an analog-to-digital converter ADCa. The decoder DEC, the operational amplifier INTb, and the analog-to-digital converter ADCa may be connected by a circuit including the plurality of switches SW1-SW6. The multifunction circuit MC may operate as a driving circuit DCa or as a test circuit TCa by changing the opening/closing state of the plurality of switches SW1-SW6.

The operational amplifier INTb may include an inverted terminal IPb1 (e.g., a second input terminal, in the claims), a non-inverted terminal IPb2 (e.g., a first input terminal, in the claims), and an output terminal OPb.

The plurality of switches SW1-SW6 may include a first switch SW1, a second switch SW2, a third switch SW3, a fourth switch SW4, a fifth switch SW5, and a sixth switch SW6. An input unit of the analog-to-digital converter ADCa may be connected to the fifth switch SW5. The first switch SW1 may be connected between the decoder DEC and the non-inverted terminal IPb2. The second switch SW2 may be connected between the analog-to-digital converter ADC and the output terminal OPb. The third switch SW3 may be connected between the inverted terminal IPb1 and a capacitor CAPb. The fourth switch SW4 may be connected between the output terminal OPb and the capacitor CAPb. The fifth switch SW5 may be connected to the output terminal OPb and the input node NN. The input node NN may be connected to one of the plurality of data lines DL1-DLm. The sixth switch SW6 may be connected between a load that outputs a reference voltage VREFb and the non-inverted terminal IPb2.

The decoder DEC may output a signal to be transmitted to the plurality of data lines DL1-DLm.

The multifunction circuit MC according to one or more embodiments of the present disclosure may further include a temperature sensor. The analog-to-digital converter ADCa may be a part of a temperature sensor. A test pad PADa may output a test data TDa to the inspection equipment IE (see FIG. 10). When an external pressure is applied, the test pad PADa may leave a trace externally. According to the present disclosure, the inspection history may be determined by checking the trace remaining on the test pad PADa. That is, it is possible to check whether the previous inspection is performed, thereby avoiding unnecessary duplicate inspections. Thus, the efficiency and reliability of the manufacturing process may be improved.

When the first switch SW1 and the fifth switch SW5 are connected, the multifunction circuit MC may operate as the driving circuit DCa. The driving circuit DCa may include an operational amplifier INTb. The operational amplifier INTb may be configured in the form of the voltage follower.

The driving circuit DCa may be configured in the form of the voltage follower to apply an output of the decoder DEC to the plurality of corresponding data lines DL1-DLm. The operational amplifier INTb may output a test signal TSa through the plurality of data lines DL1-DLm.

When the second switch SW2, the third switch SW3, the fourth switch SW4, and the sixth switch SW6 are connected, the multifunction circuit MC may operate as the test circuit TCa. When the multifunction circuit MC operates as the test circuit TCa, the test circuit TCa may perform substantially the same role as the test circuit TC (see FIG. 8). The test circuit TCa may be connected with the test pad PADa to output the test data TDa to the inspection equipment IE (see FIG. 10).

According to the present disclosure, in the inspection operation of the display panel, the EDS inspection and the array inspection may be performed in one inspection equipment (IE, refer to FIG. 10). The inspection equipment IE may be connected with the test pad PADa. In the array inspection, the MOS characteristics of the first transistor T1 (see FIG. 9A) may be inspected. The test circuit TCa to which the second switch SW2, the third switch SW3, the fourth switch SW4, and the sixth switch SW6 are connected may output the test signal TSa. The inspection equipment IE (see FIG. 10) may receive the test data TDa by probing the test pad PADa. The inspection equipment IE (see FIG. 10) may determine whether the plurality of pixels PXaa is normal by using the test data TDa. Thus, electrical inspection operations may be simplified, process efficiency may be improved, and productivity may be increased.

According to the present disclosure, the existing data-driving circuit 200 may be used as the test circuit TCa by changing the connection of the plurality of switches SW1-SW6 of the existing data-driving circuit 200 without adding a separate test circuit. In addition, the test circuit TCa fabricated by changing the connection of the plurality of switches SW1-SW6 may also be utilized as an external compensation circuit and a temperature compensation circuit. That is, utilization of the circuit may be increased, and reliability may be improved.

While the present disclosure has been described with reference to embodiments thereof, it will be apparent to those of ordinary skill in the art that various changes and modifications may be made thereto without departing from the spirit and scope of the present disclosure as set forth in the following claims. Therefore, the technical scope of the present disclosure should not be limited to the contents described in the detailed description of the specification, but should be determined by the claims, with functional equivalents thereof to be included therein.

What is claimed is:

1. An electronic device comprising:
a flexible circuit board; and
a display panel electrically connected with the flexible circuit board, and comprising:
pixels;
data lines electrically connected with the pixels;
a multiplexer configured to select at least one data line of the data lines;
a test circuit configured to convert a line signal transferred through the at least one data line into a digital signal to output test data; and
a test pad connected with the test circuit and configured to output the test data.

2. The electronic device of claim 1, wherein the multiplexer, the test circuit, and the test pad are above the display panel.

3. The electronic device of claim 1, wherein the display panel further comprises:
a timing controller configured to output an image data signal; and
a driving circuit configured to provide a data signal to the data lines based on the image data signal.

4. The electronic device of claim 1, further comprising a first chip on the flexible circuit board, and comprising a timing controller configured to output an image data signal,
wherein the display panel further comprises a driving circuit configured to provide a data signal to the data lines based on the image data signal.

5. The electronic device of claim 1, further comprising a second chip on the display panel and comprising:
a timing controller configured to output an image data signal; and
a driving circuit configured to provide a data signal to the data lines based on the image data signal.

6. The electronic device of claim 1, wherein the test circuit comprises:
an operational amplifier configured to amplify a first voltage value of the line signal to a second voltage value having a voltage level that is higher than the first voltage value; and
an analog-to-digital converter configured to convert the second voltage value into a digital signal to generate the test data output to the test pad.

7. The electronic device of claim 1, wherein the multiplexer is provided in plural, and comprises a first multiplexer and a second multiplexer, and
wherein the pixels comprise first pixels connected with the first multiplexer, and second pixels spaced apart from the first pixels in a first direction and connected with the second multiplexer.

8. The electronic device of claim 7, wherein the test circuit is provided in plural to respectively correspond to the multiplexers, and
wherein the test pad is provided in plural to respectively correspond to the test circuits.

9. An electronic device comprising:
a flexible circuit board; and
a display panel electrically connected with the flexible circuit board, and comprising:
pixels;
data lines electrically connected with the pixels; and
driving circuits electrically connected with the data lines, and comprising:
a decoder configured to receive an image data signal from outside;
an operational amplifier comprising a first input terminal, a second input terminal, and an output terminal;
an analog-to-digital converter configured to convert an analog signal into a digital signal;
a first switch connected between the decoder and the first input terminal; and
a second switch connected between the analog-to-digital converter and the output terminal.

10. The electronic device of claim 9, further comprising a first chip on the flexible circuit board, electrically connected with the display panel, and comprising a timing controller configured to output the image data signal.

11. The electronic device of claim 9, wherein the display panel further comprises a timing controller configured to output the image data signal.

12. The electronic device of claim 9, wherein the driving circuits further comprise:
a capacitor;
a third switch connected between the second input terminal and the capacitor;
a fourth switch connected between the output terminal and the capacitor; and
a fifth switch connected between the output terminal and one of the data lines.

13. The electronic device of claim 12, wherein, when the first switch and the fifth switch are connected, the driving circuits are configured to operate as voltage followers.

14. The electronic device of claim 13, wherein the driving circuits are configured to output a data voltage to the one of the data lines based on the image data signal; and
wherein the pixels are configured to receive the data voltage.

15. The electronic device of claim 12, wherein, when the second switch, the third switch, and the fourth switch are connected, the driving circuits are configured to operate as operational amplifiers.

16. The electronic device of claim 15, wherein the display panel further comprises a test pad connected with the analog-to-digital converter.

17. An inspection method of a display panel comprising a silicon wafer, a pixel circuit on the silicon wafer, a data line connected with the pixel circuit, a test circuit connected with the data line, and a test pad connected with the test circuit, the method comprising:
performing an Electrical Die Sorting (EDS) inspection on the silicon wafer through the test pad; and
performing an array inspection on the pixel circuit through the test pad by:
receiving, by the test circuit, a line signal transferred through the data line;
converting, by the test circuit, the line signal into a digital signal to output test data; and
determining whether the pixel circuit is defective based on the test data.

18. The method of claim 17, further comprising probing, by inspection equipment, the test pad prior to performing the EDS inspection and performing the array inspection.

19. The method of claim 18, wherein the inspection equipment is connected with the test pad during performing the EDS inspection and performing the array inspection.

20. The method of claim 19, wherein determining whether the pixel circuit is defective based on the test data comprises:
transmitting the test data to the test pad; and
determining, by the inspection equipment, whether the pixel circuit is defective.
